(19) United States
(12) Patent Application Publication
(10) Pub. No.: US 2011/0208895 A1
(43) Pub. Date: Aug. 25, 2011

(54) METHODS FOR MEMORY PROGRAMMING DURING PRODUCT ASSEMBLY

(75) Inventors: Michael R. Wiegers, Baldwin City, KS (US); Travis J. Hebner, Gardner, KS (US); Jay D. Schroeder, Olathe, KS (US); Ross R. Stutterheim, Overland Park, KS (US)

(73) Assignee: GARMIN LTD., Camana Bay (KY)

(21) Appl. No.: 12/710,152

(22) Filed: Feb. 22, 2010

(51) Int. Cl. G06F 12/00; G06F 15/177; G06F 12/02; G11C 5/02; G11C 16/04

(52) U.S. Cl. 711/103; 713/2; 365/51; 365/185.03; 711/E12.001; 711/E12.008

(57) ABSTRACT

A method of writing data to an electronic device during assembly comprises attaching a resident memory element to one or more contact pads of a circuit board using a solder paste; reflowing the solder paste to affix the resident memory element to the contact pads; copying data from an external memory element to the resident memory element; and thereafter combining a device component with the circuit board to at least partially complete assembly of the electronic device.

### BACKGROUND

Reflow soldering is a process commonly used to attach electronic components to a circuit board. The process uses solder paste to hold components in place on the circuit board, after which the entire circuit board is subjected to controlled heat to melt the solder and permanently attach the electrical components to the board. Reflow soldering is particularly useful for attaching surface mount components to a circuit board.

### SUMMARY

Memory elements of an electronic device may be programmed before being attached to a circuit board to reduce costs. However, reflow soldering exposes the board and any attached memory chips to extreme temperatures, and the memory, and particularly multi-level cell flash memory, may be corrupted during the process. Embodiments of the present invention solve this problem by providing improved methods of writing data to an electronic device during assembly thereof.

One embodiment of the invention is a method of writing data to an electronic device after reflow soldering but before final assembly of the device. The method may comprise temporarily attaching a resident memory element having no operational data stored thereon to a circuit board using solder paste; reflowing the solder paste to affix the resident memory element to the contact pads of the circuit board; copying operational data from an external memory element to the resident memory element after the reflow process; and then combining other device components with the circuit board to complete assembly of the electronic device. Such functionality eliminates the need to program the resident memory element before the reflow process and therefore eliminates the impact of reflow soldering on data stored on the resident memory element.

Another embodiment of the invention is a method of writing data to an electronic device from an external memory element with the assistance of a portable indicator. The method may comprise attaching a resident memory element and a processor to a circuit board; coupling an external memory element to the processor; transferring data from the external memory element to the resident memory element only if the indicator is coupled with the processor; and combining a device component with the circuit board to complete assembly of the electronic device. The method may further comprise indicating the status of the data transfer (e.g. in progress, completed, error, etc.) with the indicator. Such functionality facilitates the writing of data to the electronic device during assembly thereof and provides a quick and easy way to monitor the progress of the data transfer.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present invention are described in detail below with reference to the attached drawing figures, wherein:

FIG. 1 is a block diagram of components of an electronic device that may be assembled with the methods of the present invention along with external devices that may be used to assist with the assembly;

FIG. 2 is a flow diagram of a method of writing data to an electronic device according to an embodiment of the present invention; and

FIG. 3 is a flow diagram of a method of writing data to an electronic device according to another embodiment of the present invention.

### DETAILED DESCRIPTION OF THE EMBODIMENTS

The following detailed description references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

In general, embodiments of the present invention provide methods of writing data to an electronic device during the assembly thereof. The methods reduce or eliminate the impact of reflow soldering on data stored on resident memory elements and permit data to be easily and confidently written to an electronic device during its assembly. One embodiment comprises the steps of temporarily attaching a resident memory element having no operational data stored thereon to a circuit board using solder paste; reflowing the solder paste to affix the resident memory element to the contact pads of the circuit board; copying operational data from an external memory element to the resident memory element after the reflow process; and then combining other device components with the circuit board to at least partially complete assembly of the electronic device. Such functionality eliminates the need to program the resident memory element before the reflow process and therefore eliminates the impact of reflow soldering on data stored on the resident memory element.

Another embodiment comprises the steps of attaching a resident memory element and a processor to a circuit board; coupling an external memory element to the processor; transferring data from the external memory element to the resident memory element only if an indicator is coupled with the processor; and combining a device component with the circuit board to assemble the electronic device. The method may further comprise indicating the status of the data transfer (e.g. in progress, completed, error, etc.) with the indicator. Such functionality facilitates the writing of data to the electronic device during assembly thereof and provides a quick and easy way to monitor the progress of the data transfer.

These and other methods of the present invention are described in more detail below and may be used to assemble components of any electronic device such as a portable navigation device, a mobile phone, a portable media player, a mobile internet device, a computing device, or any other electronic device. Components of an exemplary electronic device 10 that may be assembled with methods of the present invention are illustrated in FIG. 1 and broadly comprise a processor 12 and a resident memory element 14 both mounted to a circuit board 16 or other substrate. The electronic device 10 may also include other components such as a display, a user interface, a location determining element such as a GPS receiver, and/or a housing. Also illustrated in FIG. 1 are an external memory element 18, an indicator 20, and a power supply 22 that may be used to facilitate writing of data to the electronic device 10 during assembly thereof as described below.

In more detail, the processor 12 may be any electronic device capable of executing logical and mathematical operations on data and operable to boot from either the resident memory element 14 and/or the external memory element 18. The processor 12 may be a single electronic component or it may be a combination of components that provide the requisite functionality. The processor 12 may comprise a microprocessor, a microcontroller, programmable logic controller (PLC), field-programmable gate array (FPGA), application specific integrated circuit (ASIC), or any other component or components that are operable to perform, or assist in the performance of, the required operations. In some embodiments, the processor 12 may further comprise or be coupled with a memory controller 24 to manage reading and writing of data to the resident memory element 14, the external memory element 18, or any other memory elements. In some embodiments, the memory controller may be integrated into the processor 12, and in other embodiments the memory controller may be a separate component, or omitted entirely.

The resident memory element 14 may be any electronic memory that can be accessed by the processor 12 and operable for storing instructions or data. The resident memory element 14 may be a single component or it may be a combination of components that provide the requisite functionality. The resident memory element 14 may include various types of volatile or non-volatile memory such as flash memory, optical discs, magnetic storage devices, SRAM, DRAM, or other memory devices capable of storing data and instructions. The resident memory element 14 may communicate directly with the processor 12, or it may communicate with the processor 12 over a bus or other mechanism that facilitates direct or indirect communication between the devices. The resident memory element 14 may optionally be structured with a file system to provide organized access to data existing thereon. In various embodiments, the resident memory element 14 includes a multi-level cell (MLC) flash memory element. MLC is a flash memory technology using multiple levels per cell to allow more bits to be stored as opposed to single-level cell (SLC) flash technologies, which uses a single level per cell. The resident memory element 14, including the MLC flash memory element, may employ NAND technology. The circuit board 16 may be any conventional circuit board or other type of electronic substrate operable for supporting and electrically interconnecting the other components of the electronic device. The circuit board 16 may include conventional contact pads 26 for interconnecting and powering the components of the electronic device 10.

The external memory element 18 may be any electronic memory operable for storing instructions or operational data and is preferably packaged so that it may be easily connected with and removed from the electronic device 10. The external memory element 18 may be a single component or it may be a combination of components that provide the requisite functionality. The external memory element 18 may include various types of volatile or non-volatile memory such as flash memory, optical discs, magnetic storage devices, SRAM, DRAM, or other memory devices capable of storing data and instructions and may also comprise a connector to facilitate attachment to the processor 12. For example, the external memory element 18 may include a flash memory element connected to a cable with a connector attached thereto. In this configuration, the external memory element 18 is easily attached to and removed from the processor 12 as required. The external memory element 18 may communicate directly with the processor 12, or it may communicate with the processor 12 over a bus or other mechanism that facilitates direct or indirect communication between the devices. For example, the external memory element 18 and the processor 12 may communicate over a MultiMedia Card (MMC) bus, USB bus, PC Card, Small Computer System Interface (SCSI), Serial Attached SCSI (SAS), FireWire, Peripheral Component Interconnect (PCI) Bus, PCI Express bus, or various other electronics buses. Alternately, the external memory element 18 may communicate with the processor over a cable capable of communicating an identifier to the processor. The external memory element 18 may optionally be structured with a file system to provide organized access to data existing thereon. In a particular embodiment, the external memory element may be a removable secure digital (SD) memory card that can be removably coupled with the processor 12 via an SD slot on the electronic device 10.

The indicator 20 is provided for triggering a data transfer operation and indicating the status and operation of the data transfer as described in more detail below. The indicator 20 may be any device that can communicate with the processor 12 and may be a single component or it may be a combination of components that provide the requisite functionality. In one embodiment, the indicator 20 may comprise a small circuit board or other substrate and an indicating device mounted on the circuit board such as a light-emitting diode (LED), a seven segment display, a liquid crystal display (LCD), an organic light-emitting display (OLED), a buzzer or other device operable to indicate the status or operation of a data transfer process. For example, the indicator 20 may include a green LED and a red LED, where a flashing green light may indicate a data copy operation is in progress, a steady green light may indicate the copy is complete, and a flashing red light may indicate an error. The indicator 20 may also communicate an error code by blinking in a predetermined sequence corresponding to a specific error code. Alternatively, the indicator may utilize a buzzer or other sound-generating device to emit a short sound when a copy operation is complete and emit a continuous sound when an error occurs.

The indicator 20 may communicate directly with the processor 12, or it may communicate with the processor 12 over a bus or other mechanism that facilitates direct or indirect communication between the devices. For example, the indicator 20 and the processor 12 may communicate over a MMC bus, USB bus, PC Card, SCSI bus, SAS bus, FireWire, PCI bus, PCI Express bus, or various other electronics buses.

In one embodiment, the indicator 20 is coupled with a USB bus of the processor 12 via a USB cable 28. The USB cable 28 may be a series A, series B, or mini B connector and is preferably a “keyed connector” with an ID pin and pull-down ID resistor capable of identifying the cable or other associated electronics. In order to read the ID resistor and therefore identify the cable 28, the processor 12 or a circuit attached thereto may apply a pull-up resistor to the cable's ID pin and read the voltage generated by the resultant resistor divider, consequently identifying the cable 28 or other associated electronics and related information. The processor 12 may also toggle the voltage applied to the pull-up resistor to operate the LEDs as described above to indicate the status of a data transfer operation. As explained in more detail below, this allows the presence of the USB cable 28 to trigger a data transfer operation to the resident memory element 14 and to then indicate the progress of the data transfer.

The power supply 22 may be any power source operable to power the processor 12, indicator 20, and/or other components of the electronic device 10 during assembly thereof. Because the power supply 22 is used to power-up the processor 12 before final assembly of the electronic device 10, it is preferably portable, lightweight, and capable of being quickly coupled to the processor 12, either directly or indirectly. In one embodiment, the power supply 22 may be a self-contained 5V DC power supply that plugs into a conventional 120 VAC outlet and that provides 5V DC power to the processor 12 via the indicator 20 as illustrated. In other embodiments, the power supply 22 may be built into the indicator 20 or other device or component.

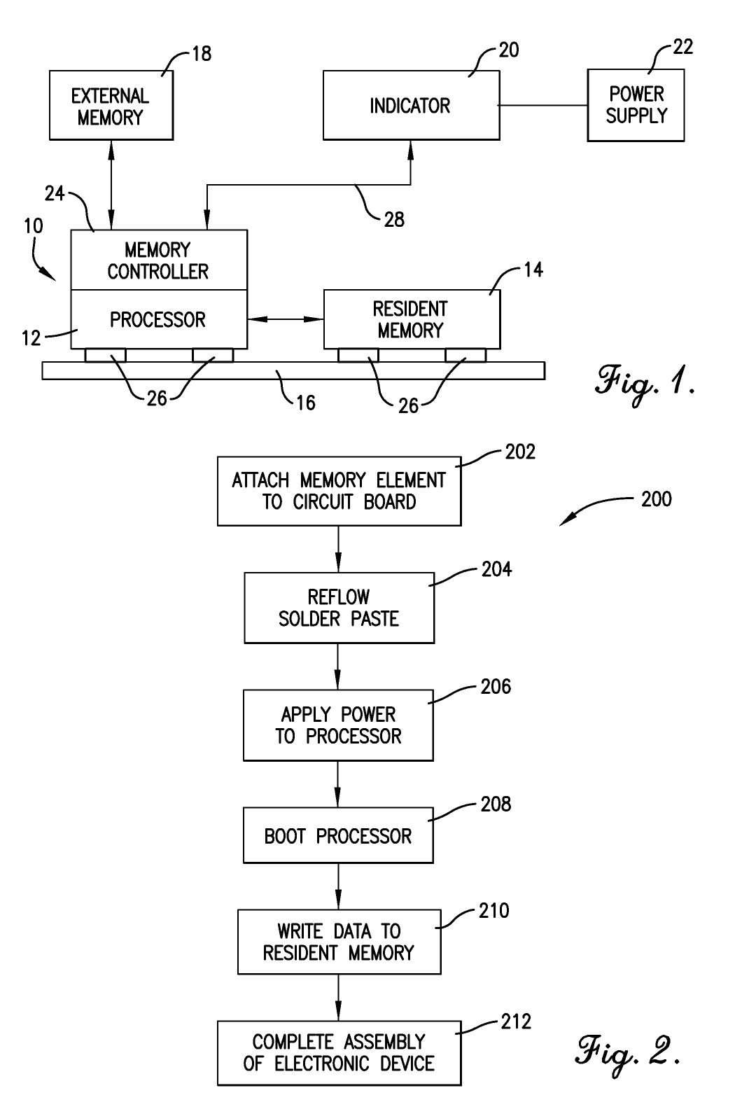

Turning now to the flow chart of FIG. 2, a method 200 that may be used to assemble components of the electronic device 10 or another electronic device in accordance with embodiments of the present invention is shown. Some of the blocks of the flow chart may represent a module segment or portion of code of a computer program which comprises one or more executable instructions for implementing the specified logical function or functions. In some alternative implementations, the functions noted in the various blocks may occur out of the order depicted in FIG. 2. For example, two blocks shown in succession in FIG. 2 may in fact be executed substantially concurrently, or the blocks may sometimes be executed in the reverse order depending upon the functionality involved. Although the steps in FIG. 2 reference the electronic device 10 of FIG. 1, the methods described herein may be used to assemble any electronic device and are not limited to the particular embodiments described herein.

An embodiment of the method of FIG. 2 writes data to the electronic device 10 after reflow soldering but before final assembly of the device. The method broadly comprises the steps of temporarily attaching the resident memory element 14 to the circuit board 16 using solder paste; reflowing the solder paste to affix the resident memory element 14 to the contact pads 26 of the circuit board; copying data from the external memory element 18 to the resident memory element 14 after the reflow process; and then combining other device components with the circuit board 16 to at least partially complete assembly of the electronic device. In some embodiments, the resident memory element 14 has no operational data stored thereon prior to its attachment to the circuit board 16. “Operational data,” as used herein, refers to data the enables operation of the device 10, such as boot instructions, operating system information, cartographic map data, media data, application executables, and the like. This eliminates the need to program the resident memory element 14 before the reflow process and therefore eliminates the impact of reflow soldering on data stored on the resident memory element 14. Application of embodiments of the present invention to the writing of cartographic map may be particularly useful due to the volume of cartographic data that must be accurately written to provide desirable navigation functionality (e.g., the cartographic data may represent map data for all of the United States, all of North America, all of Western Europe, combinations thereof, and the like).

In more detail, the processor 12 and the resident memory element 14 are first attached to the circuit board 16 with solder paste as depicted in step 202. The solder paste may be applied to the circuit board 16 using a stencil, printing, pin transfer, or screening. The processor 12 and resident memory element 14 may be laid in position by machine or by hand with the terminations, such as the contact pads 26, pins, or ball grid arrays (BGAs), of the processor 12 and memory element 14 in contact with the solder paste. Solder paste is typically viscous after dispensing and therefore maintains the position of the processor 12 and memory 14 during the manufacturing process. Additional electrical components of the electronic device described above may also be added to the circuit board and temporarily affixed with solder paste. As mentioned above, the resident memory element 14 may have no operational data stored thereon when it is first placed on the circuit board 16.

In step 204, the solder paste is reflowed to fixedly attach the processor 12 and the resident memory element 14 to the circuit board 16. The reflow process subjects the processor 12, the resident memory element 14, and the circuit board 16 to a controlled heat that melts the solder paste to evaporate solvents and cure the solder paste. After the heat is removed, the solder paste hardens, fixedly attaching the processor 12 and the resident memory element 14 to the circuit board 16 and providing electrical communication between the contact pads 26 on the circuit board 16 and the terminations of the processor and memory elements. As discussed above, this reflow process can compromise the integrity of any data stored on the resident memory element 14, but this is not a concern with embodiments of the present invention because the resident memory element 14 has no operational data stored on it at this point in the method.

In step 206, power is applied to the processor 12. In some embodiments, the power is supplied via the portable power supply 22 to facilitate writing of data to the electronic device 10 while it is being assembled.

In step 208, the processor 12 is booted. Because the resident memory element 14 has no operational data stored thereon at this point in the method, the processor 12 is booted from the external memory element 18. The processor 12 may boot from the external memory element 18 by accessing and running a bootstrap program on the external memory element or by any conventional method.

In step 210, operational data is written to the resident memory element 14. The data may be written to the resident memory element 14 by accessing the external memory element 18 with the processor 12 and transferring the data from the external memory element 18 to the resident memory element 14. After the operational data is written to the resident memory element 14, the processor 12 may boot from the resident memory element 14 without reliance on the external memory element 18.

In step 212, the final assembly of the electronic device is completed. For example, additional device components, such as the display, device housing, satellite navigation (GPS) receivers, etc. discussed above may be attached to or otherwise coupled with the circuit board 16 and an outer housing or enclosure may be placed over the circuit board and attached device components.

The method 200 advantageously eliminates the need to program the resident memory element 14 before the reflow process and therefore reduces or eliminates the impact of reflow soldering on data stored on the resident memory element 14. The method 200 also permits data to be easily and confidently written to the resident memory element during the assembly of the electronic device 10.

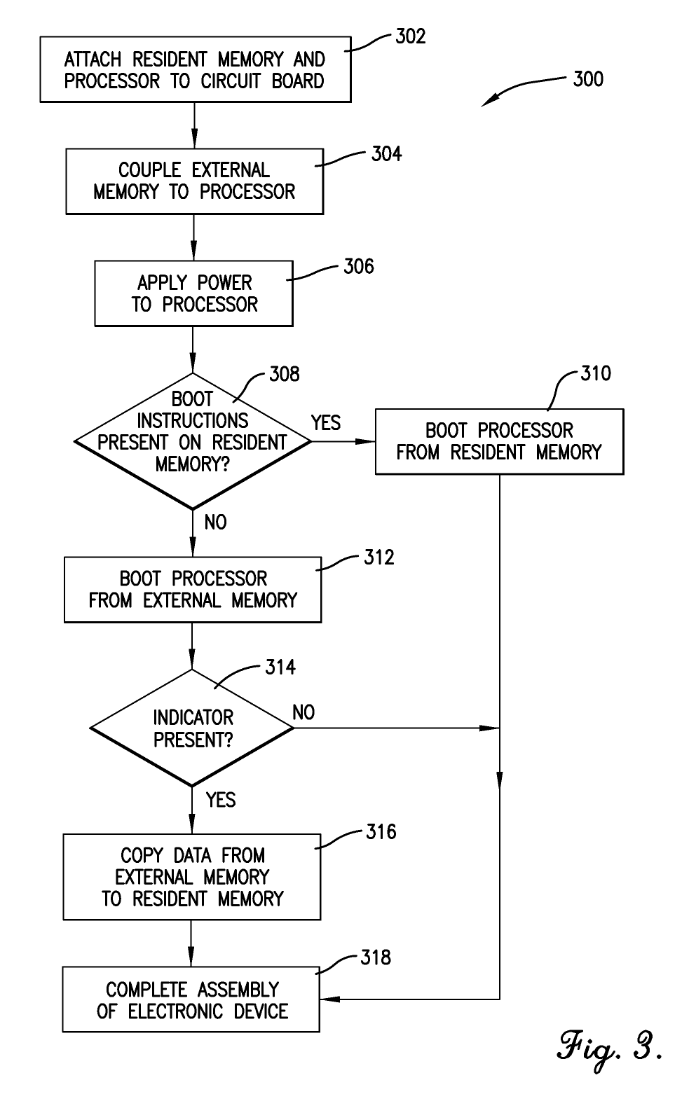

FIG. 3 illustrates another method 300 that may be used to assemble the components of the electronic device 10 or another electronic device in accordance with an embodiment of the present invention. The method 300 is similar to the method 200, except that with method 300, the writing of data to the resident memory 14 may be triggered by and monitored with the indicator 20.

As with the flow chart of FIG. 2, some of the blocks of the flow chart of FIG. 3 may represent a computer program or portions thereof executable by the processor 12 or other device. The particular order of the steps illustrated in FIG. 3 and described herein can be altered without departing from the scope of the invention. For example, some of the illustrated steps may be reversed, combined, or even removed entirely. Although the steps in FIG. 3 reference the electronic device 10 of FIG. 1, the methods described herein may be used to assemble any electronic device and are not limited to the particular embodiments described herein.

An embodiment of the method of FIG. 3 comprises attaching the resident memory element 14 and the processor 12 to the circuit board 16; coupling the external memory element 18 to the processor 12; transferring data from the external memory element 18 to the resident memory element 14 only if the indicator 20 is coupled with the processor; and combining additional device components with the circuit board 16 to complete the assembly of the electronic device 10. The method may further comprise the step of indicating the status of the data transfer (e.g. in progress, completed, error, etc.) with the indicator 20. Such functionality facilitates the writing of data to the electronic device 10 during its assembly and provides a quick and easy way to monitor the progress of the data transfer.

In more detail, the method 300 begins at step 302 where the processor 12 and resident memory element 14 are attached to the circuit board 16 with solder paste. As with the method 200, the solder paste may be applied to the circuit board 16 using a stencil, printing, pin transfer, or screening, and the processor 12 and resident memory element 14 may be laid in position by machine or by hand with the terminations, such as the contact pads 26, pins, or ball grid arrays (BGAs), of the processor 12 and memory element 14 in contact with the solder paste. Additional electrical components of the electronic device 10 described above may also be added to the circuit board and temporarily affixed with solder paste.

In the embodiments of FIG. 3, the resident memory element 14 may have operational data stored thereon before it is placed on the circuit board 16. Thus, the instructions and data may be corrupted during the reflow process, a solution to which is explained below.

In step 304, the solder paste is reflowed to fixedly attach the processor 12 and the resident memory element 14 to the circuit board 16. As described above, the reflow process subjects the processor 12, resident memory element 14, and circuit board 16 to a controlled heat that melts the solder paste to evaporate solvents and cure the solder paste. After the heat is removed, the solder paste hardens, fixedly attaching the processor 12 and resident memory element 14 to the circuit board 16 and providing electrical communication between the contact pads 26 on the circuit board 16 and the terminations of the processor and memory elements. As discussed above, this reflow process can compromise the integrity of any operational data stored on the resident memory element 14.

In step 306, power is applied to the processor 12. In some embodiments, the power is supplied via the portable power supply 22 to facilitate writing of data to the electronic device 10 while it is being assembled.

In step 308, the processor 12 determines whether it can boot from the resident memory element 14. The processor may do so by determining whether a bootstrap program or other executable code is present on the resident memory element 14. For example, the processor may retrieve data from the resident memory element 14 and sequentially scan through the data to determine if valid boot instructions are contained on the resident memory element 14. The processor 12 may also scan for a predetermined filename from a file system existing on the resident memory element 14. The processor 12 may validate one instruction or file name, or it may validate a number of instructions or file names, as required under the circumstances. Additionally, the processor 12 may compare data retrieved from the resident memory element 14 to checksums, CRC or other error-detection or error-correction codes to validate the presence of instructions.

If the processor 12 determines boot instructions are present on the resident memory element 14 in step 308, the method proceeds to step 310 where the processor 12 can execute the boot instructions from the resident memory element 14 (before or after final assembly of the electronic device 10). The method then proceeds to step 318 for final assembly of the electronic device 10 as described in more detail below.

However, if the processor 12 determines that no boot instructions are present in step 308, or if the boot instructions are not executable, the method proceeds to step 312 where the processor 12 boots from the external memory element 18. As with booting from the resident memory element 14 described above, booting from the external memory element may comprise accessing a bootstrap program or otherwise retrieving operational data from the external memory element 18.

After the processor 12 has booted, it determines whether the proper indicator 20 has been coupled to the processor in step 314. This may be accomplished by verifying the USB cable 28 corresponds to a proper, pre-defined, indicator. In order to read the ID resistor and therefore identify the cable 28, the processor 12 or a circuit attached thereto may apply a pull-up resistor to the cable's ID pin and read the voltage generated by the resultant resistor divider, consequently identifying the cable 28 and thus whether the cable 28 is a proper indicator. The processor may also toggle the voltage applied to the pull-up resistor to operate the LEDs as described above to indicate the status of a data transfer operation. As explained in more detail below, this allows the presence of the USB cable 28 to trigger a data transfer operation and to indicate the status of the data transfer.

If step 314 determines that the indicator 20 is not coupled with the processor 12, or that the wrong cable is coupled between the processor 12 and the indicator 20, data is not written from the external memory element 18 to the resident memory element 14. Instead, the method proceeds to step 318 for final assembly of the electronic device 10 as described in more detail below. Alternatively, the indicator 20 may present an error message to indicate the use of an improper cable.

However, if the processor 12 determines that the proper cable 28 and/or indicator 20 are attached, the method proceeds to step 316 where the processor 12 copies the contents of the external memory element 18 to the resident memory element 14. The copying may utilize direct memory access (DMA), individual read and write operations, or any other method of copying data from the external memory element 18 to the resident memory element 14. The copying may be performed in one operation or as a series of operations. The indicator 20 may also indicate the status of the copy operation. For example, the processor 12 may selectively toggle the voltage applied to the USB cable 28 to flash a green LED to indicate a copy operation is in progress, to provide a steady green light to indicate copying is complete, or flash a red LED to indicate an error.

After the processor 12 has written instructions and data from the external memory element 18 to the resident memory element 14, the method proceeds to step 318 where the final assembly of the electronic device 10 is completed. For example, additional device components, such as the display, receivers, etc. discussed above may be attached to or otherwise coupled with the circuit board 16 and an outer housing or enclosure may be placed over the circuit board and attached device components.

The method 300 enables data to be quickly, easily, and confidently copied from the external memory element 18 to the resident memory element 14 after a reflow process but during the assembly of the electronic device 10. This saves time, ensures data integrity, and reduces or even eliminates the number of electronic devices that must be reprogrammed after final assembly.

Some of the steps in methods 200 and 300 may be performed with one or more computer programs. The computer program may be stored in or on a computer-usable medium, such as the resident memory element 14, the external memory element 18, or any other memory element residing on or accessible by the processor 12 to implement the procedures and their other functions as described herein. The computer programs may each comprise an ordered listing of executable instructions for implementing logical or mathematical functions in the processor 12 or other device. The computer programs can be embodied in any computer-usable medium for use by or in connection with an instruction execution system, apparatus, or device, such as a computer-based system, processor-containing system, or other system that can fetch the instructions for the instruction execution system, apparatus, or device, and execute the instructions.

In the context of this application, a “computer-readable medium” can be any means, including the resident memory element 14 or external memory element 18, that can contain, or store the program for use by or in connection with the electronic digital processor system, apparatus, or device. The computer-readable medium can be, for example, but not limited to, an electronic, magnetic, optical, electro-magnetic, or semi-conductor system, apparatus, or device. More specific, although not inclusive, examples of the computer-readable medium would include the following: a portable computer diskette, a hard drive, a random access memory (RAM), a read-only memory (ROM), an erasable, programmable, read-only memory (EPROM or Flash memory), a DVD read-only memory (DVD-ROM), and a portable compact disk read-only memory (CDROM).

Although embodiments of the invention have been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A method of writing data to an electronic device during assembly thereof, the method comprising:
(a) attaching a resident memory element having no cartographic map data stored thereon to one or more contact pads of a circuit board using a solder paste, wherein the resident memory element is a MLC flash memory element;
(b) reflowing the solder paste to affix the resident memory element to the one or more contact pads of the circuit board;
(c) after (b), copying cartographic map data from an external memory element to the resident memory element; and
(d) after (c), combining a device component with the circuit board to at least partially complete the assembly of the electronic device.

2. The method of claim 1, wherein the device component comprises a satellite navigation receiver, an electronic display, an exterior housing, or a processor.

3. The method of claim 1, wherein the external memory element is a removable memory card.

4. The method of claim 1, wherein the data is copied to the resident memory element by accessing the external memory element with a processor associated with the resident memory element and transferring data from the external memory element to the resident memory element.

5. The method of claim 4, wherein the electronic device is a personal navigation device.

6. The method of claim 5, further comprising the step of coupling an indicator to the processor.

7. The method of claim 6, wherein the data is copied from the external memory element to the resident memory element only if the indicator is coupled with the processor.

8. The method of claim 6, wherein the indicator is coupled with the processor via a USB cable.

9. The method of claim 1, further comprising the step of booting a processor associated with the resident memory element from the external memory element before step (c).

10. A method of writing data to an electronic device during assembly thereof, the method comprising:
(a) attaching a resident memory element and a processor to a plurality of contact pads of a circuit board using a solder paste, wherein the resident memory element is a MLC flash memory element;
(b) reflowing the solder paste to affix the resident memory element and the processor to the plurality of contact pads of the circuit board;
(c) coupling an external memory element and an indicator with the processor, the indicator being coupled with the processor using a USB cable;
(d) providing power to the processor;
(e) permitting the processor to boot from the external memory element;
(f) after (e), only if the indicator is coupled with the processor, writing operational data from the external memory element to the resident memory element; and
(g) after (f), completing assembly of the electronic device.

11. The method of claim 10, wherein the completing assembly step comprises combining additional device components to the circuit board, the additional device components including a satellite navigation receiver, an electronic display, or an exterior housing for the electronic device.

12. The method of claim 10, wherein the transferred operational data includes boot instructions, operating instructions, application software, or cartographic map data.

13. A method of writing data to an electronic device during assembly thereof, the method comprising:
(a) attaching a resident memory element and a processor to a circuit board, wherein the resident memory element is a MLC flash memory element;
(b) coupling an external memory element to the processor;
(c) transferring data from the external memory element to the resident memory element only if an indicator is coupled with the processor; and
(d) after (c), combining a device component with the circuit board to at least partially assemble the electronic device.

14. The method of claim 13, further comprising:
attempting to boot the processor from the resident memory element; and
if the processor cannot boot from the resident memory element, booting the processor from the external memory element.

15. The method of claim 13, wherein the data comprises boot instructions, operating instructions, application software, or cartographic map data.

16. The method of claim 13, wherein the indicator is coupled with the processor via a USB cable.

17. The method of claim 16, wherein the USB cable is a keyed cable, and wherein the data is transferred from external memory element to the resident memory element only if the processor determines the USB cable is an identified cable.

18. The method of claim 13, wherein the indicator indicates a status of the data transfer.

19. The method of claim 13, wherein the device component comprises a satellite navigation receiver, an electronic display, an exterior housing for the electronic device, or a processor.
